(19) United States
(12) Patent Application Publication
(10) Pub. No.: US 2008/0217775 A1
(43) Pub. Date: Sep. 11, 2008

(54) Method of forming contact plugs for eliminating tungsten seam issue

(75) Inventors: Chih-Yang Pai, Hsinchu (TW); Wen-Chuan Chiang, Hsinchu (TW); Chung-Yi Yu, Hsinchu (TW); Yeur-Luen Tu, Taichung (TW); Yuan-Hung Liu, Hsinchu (TW); Hsiang-Fan Lee, Hsinchu (TW); Chuan-Jong Wang, Hsinchu (TW)

Correspondence Address: BIRCH STEWART KOLASCH & BIRCH, PO BOX 747, FALLS CHURCH, VA, 22040-0747, US

(73) Assignee: TAIWAN SEMICONDUCTOR MANUFACTURING CO., LTD.

(21) Appl. No.: 11/714,770

(22) Filed: Mar. 7, 2007

(51) Int. Cl. H01L 23/52; H01L 21/4763

(52) U.S. Cl. 257/751; 257/763; 438/643; 438/648; 257/E21.495; 257/E23.141

(57) ABSTRACT

A method of forming a contact plug of an eDRAM device includes the following steps: forming a tungsten layer with tungsten seam on a dielectric layer to fill a contact hole; removing the tungsten layer from the top surface of the dielectric layer, recessing the tungsten layer in the contact hole to form a recess of about 600˜900 Angstroms in depth below the top surface of the dielectric layer, depositing a conductive layer on the dielectric layer and the recessed tungsten plug to fill the recess; and removing the conductive layer from the top surface of the dielectric layer to form a conductive plug on the recessed tungsten plug in the contact hole.

### TECHNICAL FIELD

The present invention relates to a fabrication method of forming contact plugs for embedded dynamic random access memory (eDRAM) applications, and particularly to a fabrication method of forming tungsten contact plugs for eliminating tungsten seam issues.

### BACKGROUND

Continuing advances in semiconductor manufacturing processes have resulted in semiconductor devices with finer features and/or higher degrees of integration. Among the various features included within a semiconductor device, contact structures typically provide an electrical connection between circuit devices and/or interconnection layers. A typical contact structure may include forming a contact hole in an interlevel dielectric (ILD) and then filling the contact hole with a conductive material, for example, a tungsten material, however, encountering difficulties in metal filling process as the contact aspect ratio continues to increase. The conventional method of forming a tungsten contact plug includes plasma etching of an opening, photoresist striping and cleaning, adhesion layer and barrier metal deposition by physical vapor deposition (PVD) and tungsten deposition by PECVD. After tungsten plug filling, voids (so-called tungsten seams) are often observed in the tungsten plug. Such tungsten seams are commonly exposed during subsequent removal processing. Moreover, in certain situations the size of the tungsten seam is increased due to exposure to the removal process. This often creates a difficult topology for subsequent metallization coverage as well as electrical device degradation, which is especially apparent as leakage in metal-insulator-metal (MIM) and metal-insulator-silicon (MIS) capacitor structures. For embedded dynamic random access memory (eDRAM) applications, the tungsten seams have a strong impact on fail bit count. Although a thinner high-k material (such as Al₂O₃) used in a crown-shaped capacitor can improve 90 nm-process eDRAM device yield, developing a method of fully eliminating the tungsten seams is still needed.

### SUMMARY OF THE INVENTION

Embodiments of the present invention include methods of forming tungsten contact plugs for eliminating tungsten seams in eDRAM applications.

In one aspect, the present invention provides a method of forming a contact plug of an eDRAM device includes the following steps: forming a contact hole in a dielectric layer to expose a portion of a semiconductor substrate; forming a tungsten layer with tungsten seam therein on the dielectric layer to fill the contact hole; removing the tungsten layer from the top surface of the dielectric layer, recessing the tungsten layer in the contact hole to form a recess of about 600˜900 Angstroms in depth below the top surface of the dielectric layer, depositing a conductive layer on the dielectric layer and the recessed tungsten plug to fill the recess; and removing the conductive layer from the top surface of the dielectric layer to form a conductive plug on the recessed tungsten plug in the contact hole.

In another aspect, the present invention provides an eDRAM device has a semiconductor substrate including a dielectric layer formed thereon. The dielectric layer has a contact hole exposing a portion of the semiconductor substrate. A tungsten plug fills a lower portion of the contact hole, wherein the tungsten plug has a tungsten seam therein. A conductive plug disposes on the tungsten plug and fills an upper portion of the contact hole. The conductive plug is leveled off with the top of the dielectric layer and has a thickness of 250˜400 Angstroms.

### BRIEF DESCRIPTION OF THE DRAWINGS

The aforementioned objects, features and advantages of this invention will become apparent by referring to the following detailed description of the preferred embodiments with reference to the accompanying drawings, wherein:

FIG. 1 to FIG. 5 are cross-sectional diagrams illustrating an exemplary embodiment of a method of forming tungsten contact plugs for eliminating tungsten seam issues.

### DETAILED DESCRIPTION OF ILLUSTRATIVE EMBODIMENTS

Embodiments of the present invention provide methods of forming tungsten contact plugs to eliminate tungsten seams. For eDRAM applications, the inventive method can decrease failure bit count to improve device yield. Reference will now be made in detail to the present embodiments, examples of which are illustrated in the accompanying drawings. Wherever possible, the same reference numbers are used in the drawings and the description to refer to the same or like parts. In the drawings, the shape and thickness of one embodiment may be exaggerated for clarity and convenience. This description will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be present.

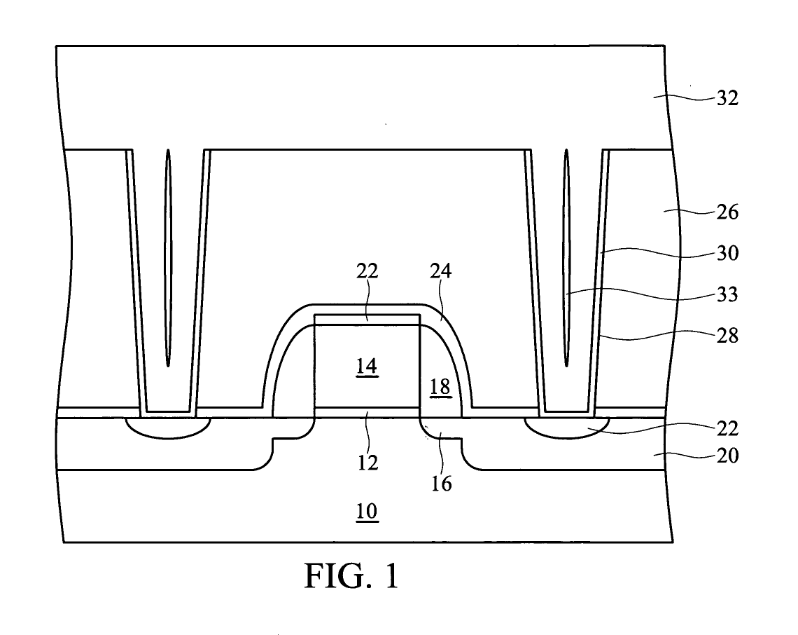

Herein, cross-sectional diagrams of FIG. 1 to FIG. 5 illustrate an exemplary embodiment of a method of forming tungsten contact plugs for eliminating tungsten seam issues.

In FIG. 1, a gate dielectric material and a gate conductive material deposited on a semiconductor substrate 10 are patterned and respectively become a gate dielectric layer 12 and a gate electrode layer 14, both of which form together as a gate structure on an embedded DRAM array region. The substrate 10 is bulk silicon, but other commonly used materials and structures such as silicon on insulator (SOI) or a silicon layer overlying a bulk silicon germanium may also be used. The gate dielectric layer 12 may be formed of silicon oxide or a high-k dielectric material. The gate electrode layer 14 may be formed of amorphous polysilicon, doped polysilicon, metal, single crystalline silicon or other conductive materials. A light ion implantation process is then performed to form two lightly doped regions 16 respectively at each side of the gate structure in the substrate 10. Next, a dielectric spacer 18 is formed on each sidewall of the gate structure. The dielectric spacer 18 may be formed of oxide, nitride, oxynitride, or combinations thereof. A heavy ion implantation process is then performed to form a heavily doped region 20 on the lightly doped region 16. Thus, two source/drain regions 20 with a lightly doped drain (LDD) structure 16 are formed in the substrate 10 at each side of the gate structure. Whether a MOS transistor is nMOS or pMOS will depend on the conductivity type of the substrate 10 and the source/drain regions 20. For pMOS transistors, the LDD structure and the source/drain regions will be p-type and the substrate will be n-type. For nMOS transistors, the LDD structure and the source/drain regions will be n-type and the substrate will be p-type. In order to reduce sheet resistance, a silicide layer 22 is formed on the source/drain regions 20 and the gate electrode layer 14. The silicide layer 22 is a metal silicide layer comprising metals such as titanium, cobalt, nickel, palladium, platinum, erbium, and the like.

Referring to FIG. 1, a contact etch stop layer (CESL) 24 for controlling the end point during subsequent contact hole formation is deposited on the above-described MOS transistor completed on the substrate 10. The CESL 24 may be formed of silicon nitride, silicon oxynitride, silicon carbide, or combinations thereof. A first inter-layered dielectric (ILD) layer 26 of about 4000˜5000 Angstroms in thickness is formed on the CESL 24 so as to isolate the MOS transistor from a subsequent formation of an interconnect structure. The first ILD layer 26 may be a silicon oxide containing layer formed of doped or undoped silicon oxide by a thermal CVD process or high-density plasma (HDP) process, e.g., undoped silicate glass (USG), phosphorous doped silicate glass (PSG) or borophosphosilicate glass (BPSG). Alternatively, the first ILD layer 26 may be formed of doped or P-doped spin-on-glass (SOG), PTEOS, or BPTEOS. Following planarization, e.g., chemical mechanical planarization (CMP) on the first ILD layer 26, a dielectric anti-reflective coating (DARC) or/and a bottom anti-reflectance coating (BARC) and a lithographically patterned photoresist layer are provided, which are omitted in the Figures for simplicity and clarity. A dry etching process is then carried out to form contact holes 28 that pass though the first ILD layer 26 and the CESL 24 so as to expose the silicide layers 22 positioned over the source/drain regions 20. Then the patterned photoresist and the BARC layer are stripped.

Referring to FIG. 1, a barrier layer 30 is conformally deposited on the resulted structure via the use of sputtering technology in order to optimize the contact resistance of subsequent overlying materials, to provide excellent adhesion to the oxide sidewalls of the contact hole 28, and to protect underlying materials from the deleterious effects of by-products produced during subsequent processing. The barrier layer 30 extending along the sidewalls of the contact hole 28 includes a titanium layer, a titanium nitride layer, or combinations thereof. A tungsten layer 32 is next deposited using LPCVD processing, to a thickness between about 6000 to 8000 Angstroms. The mechanism of filling high aspect ratio holes with LPCVD metallization always causes undesirably large grain, resulting in unwanted tungsten seams 33 in the tungsten-filled contact.

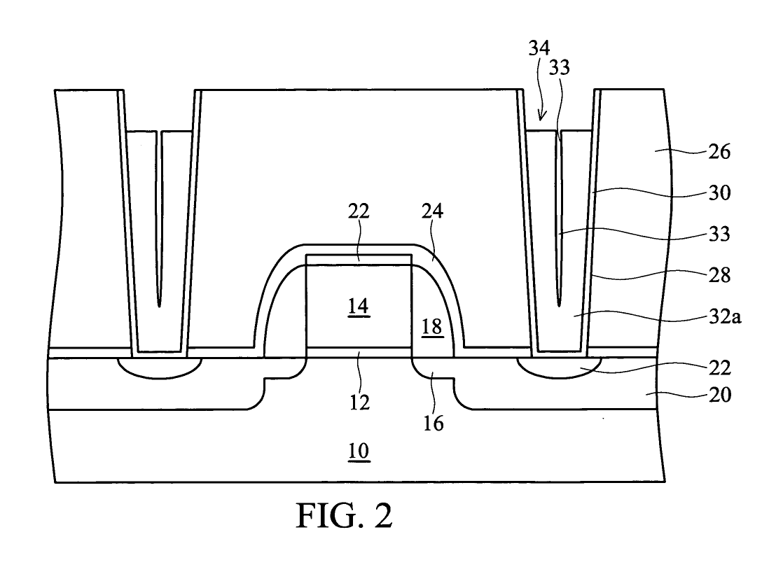

In FIG. 2, a dry etch process, for example a selective RIE etch back process using SF₆, nitrogen and chlorine as an etchant and having high etch selectivity to oxide, is performed to remove unwanted tungsten material from the region outside the contact holes 28, and then the etch back process is extended to recess the tungsten layer 32 in the contact hole 28, thus creating a recess 34 of about 600˜900 Angstroms in depth below the top surface of first ILD layer 26 and of about 0.1 to 0.15 um in diameter on the recessed tungsten contact plug 32a. In one embodiment, the extended etch back process may make the seam 33 become larger.

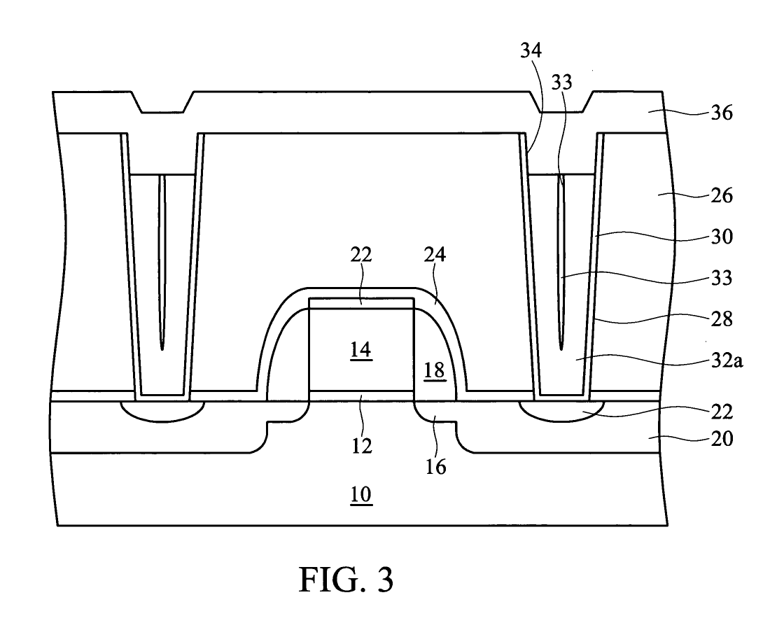

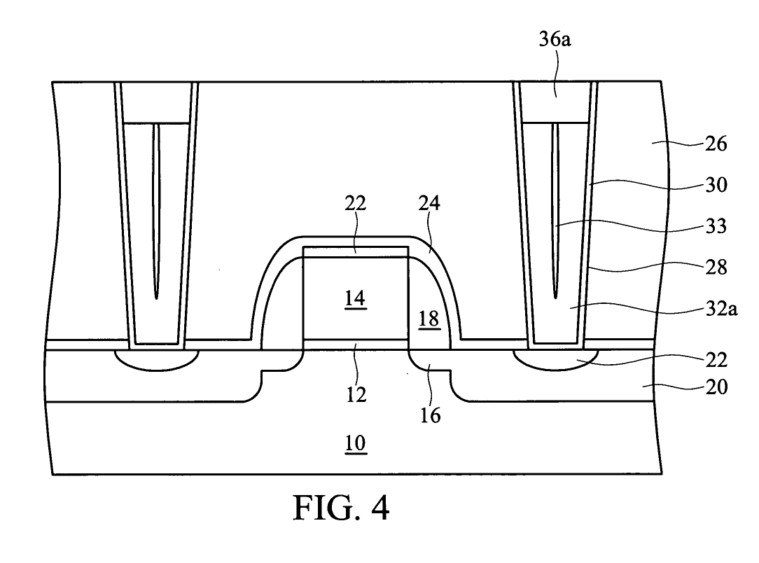

In FIG. 3, a conductive material layer 36 is deposited on the resulted structure to a thickness between about 15000 to 2500 Angstroms to fill the recess 34 and seal the cleft of the tungsten seams 33. The conductive material layer 36 may be formed through LPCVD, PECVD, MOCVD, ALD or other advance deposition technology. Preferably, the conductive material layer 36 is formed of tungsten. In some embodiments, the conductive material layer 36 is formed of copper, molybdenum (Mo), titanium nitride (TiN), tungsten-containing conductive material, or combinations thereof. Next, as shown in FIG. 4, an etch back procedure such as a CMP process or a RIE process, is used to remove the conductive material layer 36 from the surface of first ILD layer 26. In detailed, this levels off the top of the conductive material layer 36 with the top of the first ILD layer 26. This completes a conductive plug 36a with a thickness between 250 to 400 Angstroms on the top of the recessed tungsten contact plug 32a. The conductive plug 36a is a seam free plug, which also isolates the tungsten seam 33 in the recessed tungsten plug 32a from subsequent metallization. The elimination of tungsten seam issue can decrease failure bit count to improve device yield for eDRAM product applications.

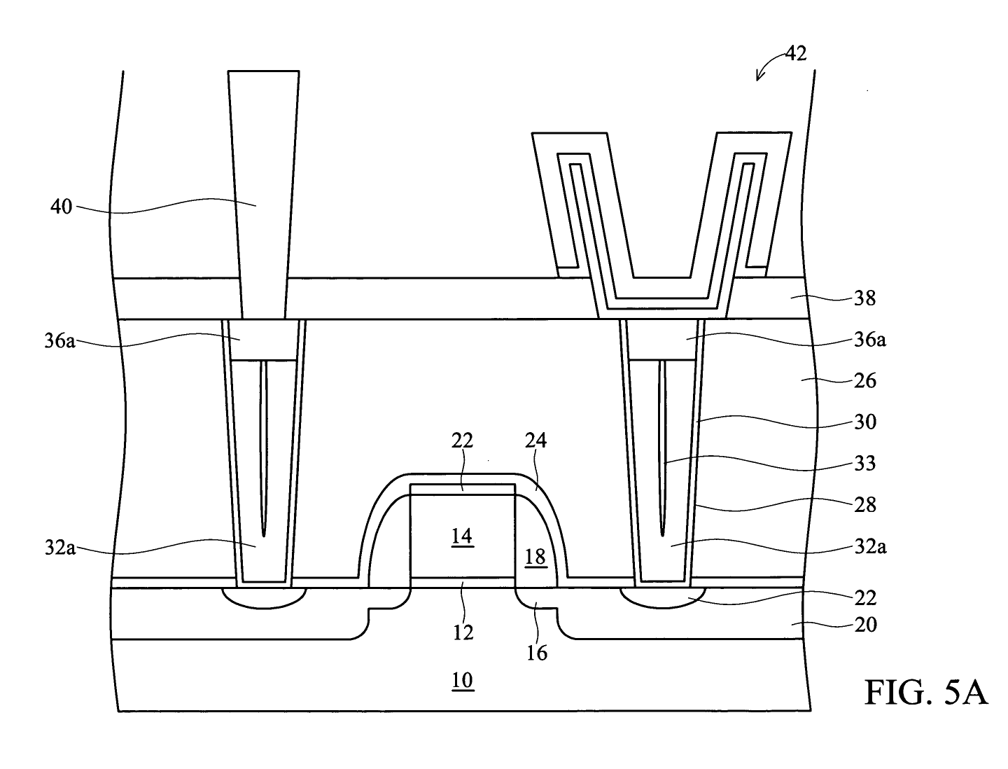

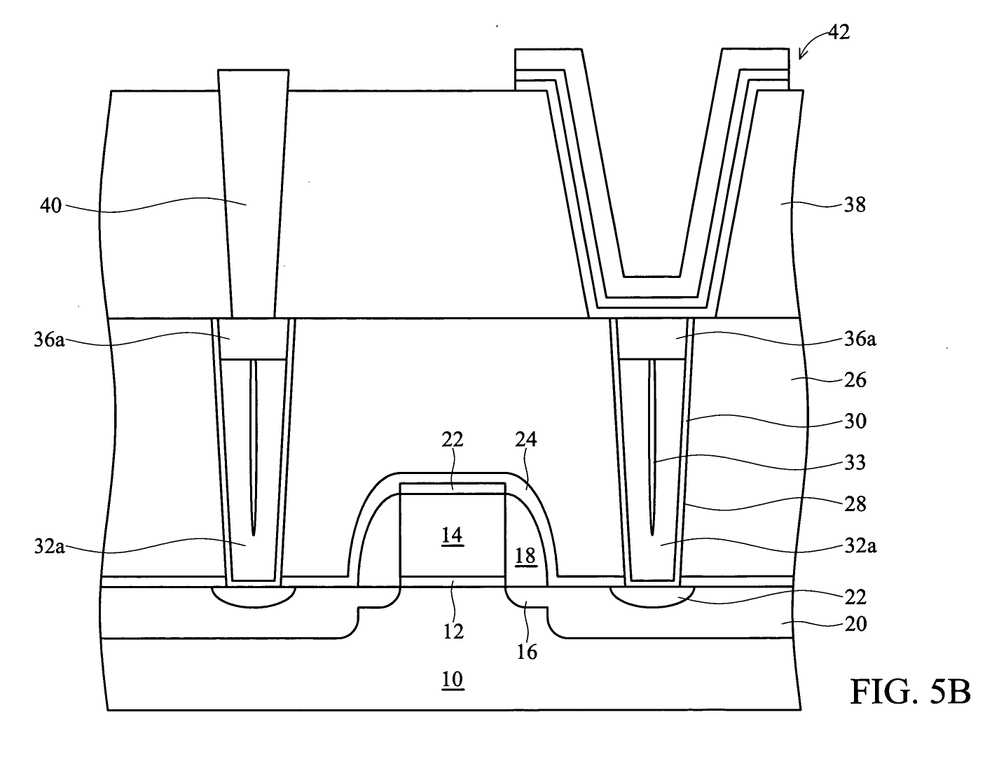

FIG. 5A and FIG. 5B show the following processes including forming a second ILD layer 38 on the conductive plug 36a and the first ILD layer 26, forming a second contact plug 40 in the second ILD layer 38 for electrically connecting one of the underlying conductive plugs 36a, and forming a capacitor structure 42 in the second ILD layer 38 for electrically connecting one of the underlying conductive plugs 36a. In an embodiment, a recess crown module is shown in FIG. 5A. In an embodiment, a non-recess crown module is shown in FIG. 5B. For MIS (metal-insulator-silicone) structure applications, the capacitor structure 42 is a crown module comprises a polysilicon cell plate, a capacitor dielectric layer, and a crown-shaped storage node structure featuring a hemispherical grain (HSG) selectively grown on the exposed surfaces of polysilicon layer. For MIM (metal-insulator-metal) structure applications, the capacitor structure 42 is a crown module comprises a metal cell plate formed of TiN or other conductive material, a capacitor dielectric layer, and a crown-shaped metal storage node structure formed of TiN or other conductive material.

Although the present invention has been described in its preferred embodiments, it is not intended to limit the invention to the precise embodiments disclosed herein. Those skilled in this technology can still make various alterations and modifications without departing from the scope and spirit of this invention. Therefore, the scope of the present invention shall be defined and protected by the following claims and their equivalents.

What is claimed is:

1. A method of forming a contact plug of an eDRAM device, comprising:
forming a dielectric layer overlying a semiconductor substrate;
forming a contact hole in said dielectric layer to expose a portion of said semiconductor substrate;
depositing a tungsten layer on said dielectric layer to fill said contact hole, wherein a tungsten seam is formed in said tungsten layer in said contact hole;
performing a dry etch process to remove said tungsten layer from the top surface of said dielectric layer and recess said tungsten layer in said contact hole to form a recess of about 600˜900 Angstroms in depth below the top surface of said dielectric layer, thereby forming a recessed tungsten plug in said contact hole;
depositing a conductive layer on said dielectric layer and said recessed tungsten plug to fill said recess; and
removing said conductive layer from the top surface of said dielectric layer to form a conductive plug on said recessed tungsten plug in said contact hole.

2. The method of claim 1, wherein said conductive layer comprises tungsten.

3. The method of claim 1, wherein said conductive layer comprises Mo, TiN, Cu, or combinations thereof.

4. The method of claim 1, wherein said recess is of 0.1˜0.15 μm in diameter.

5. The method of claim 1, wherein said conductive plug seals said tungsten seam in said recessed tungsten plug.

6. The method of claim 1, wherein said dielectric layer has a thickness of between 4000 to 5000 Angstroms.

7. The method of claim 1, wherein said dry etch process uses SF₆, nitrogen and chlorine as etchant to recess said tungsten layer in said contact hole.

8. The method of claim 1, further comprising forming a barrier layer extending along the sidewall and bottom of said contact hole before depositing a tungsten layer.

9. The method of claim 8, wherein said barrier layer comprises a titanium layer, a titanium nitride layer, or combinations thereof.

10. The method of claim 1, wherein said conductive plug is a seam free plug.

11. An eDRAM device, comprising:
a semiconductor substrate comprising a dielectric layer formed thereon, wherein said dielectric layer has a contact hole exposing a portion of said semiconductor substrate;
a tungsten plug filling a lower portion of said contact hole, wherein said tungsten plug has a tungsten seam therein; and
a conductive plug disposing on said tungsten plug and filling an upper portion of said contact hole, wherein said conductive plug is leveled off with the top of said dielectric layer and has a thickness of 250˜400 Angstroms.

12. The eDRAM device of claim 11, wherein said conductive plug comprises tungsten.

13. The eDRAM device of claim 11, wherein said conductive plug comprises Mo, TiN, Cu, or combinations thereof.

14. The eDRAM device of claim 11, wherein said conductive plug is of 0.1˜0.15 μm in diameter.

15. The eDRAM device of claim 11, wherein said conductive plug seals said tungsten seam in said tungsten plug.

16. The eDRAM device of claim 11, wherein said dielectric layer has a thickness of between 4000 to 5000 Angstroms.

17. The eDRAM device of claim 11, further comprising a barrier layer extending along the sidewall and bottom of said contact hole and sandwiched between said dielectric layer and said tungsten plug.

18. The eDRAM device of claim 17, wherein said barrier layer comprises a titanium layer, a titanium nitride layer, or combinations thereof.

19. The eDRAM device of claim 11, wherein said conductive plug is a seam free plug.
